(19) United States
(12) Patent Application Publication
(10) Pub. No.: US 2025/0280576 A1
(43) Pub. Date: Sep. 4, 2025

(54) SEMICONDUCTOR COMPONENT AND METHOD FOR PRODUCTION

(71) Applicant: Robert Bosch GmbH, Stuttgart (DE)

(72) Inventors: Christian Huber, Ludwigsburg (DE); Jens Baringhaus, Sindelfingen (DE); Kevin Dannecker, Reutlingen (DE); Max Reimer, Stuttgart (DE); Stefan Regensburger, Renningen (DE)

(21) Appl. No.: 19/061,003

(22) Filed: Feb. 24, 2025

(30) Foreign Application Priority Data
Mar. 1, 2024 (DE) 10 2024 201 915.1

(51) Int. Cl. H10D 62/10; H10D 30/01; H10D 30/66; H10D 62/00; H10D 62/85

(52) U.S. Cl. CPC H10D 62/109; H10D 30/0297; H10D 30/668; H10D 62/054; H10D 62/8503

(57) ABSTRACT

A semiconductor component, in particular a transistor, which is based on gallium nitride. The semiconductor component includes: a substrate layer and/or drain layer, a first-type-doped drift layer, a channel layer, which is second-type-doped, and a first-type-doped source layer, wherein the channel layer is arranged in the vertical direction between the source layer and the drift layer. The semiconductor component has a gate trench, which extends in the vertical direction from the source layer to the drift layer and is adjacent to the channel layer and at least a portion of the source layer. The semiconductor component has one or more second-type-doped shielding regions, each of which is located at least partially in the vertical direction below the gate trench and at least partially within the drift layer, wherein one or the plurality of shielding regions are diffused. A method for producing a semiconductor component is also described.

### FIELD

The present invention relates to a semiconductor component, in particular a transistor, in particular a so-called trench MOSFET, and to a method for producing such a semiconductor component.

### BACKGROUND INFORMATION

Field-effect transistors, in particular so-called MOSFETs or MISFETs, are used in various fields. A variant thereof are so-called trench MOSFETs or T-MOSFETs, in which one channel is vertical. In this case, for example, an n-doped source layer and a channel layer located between this source layer and one of the n-doped drift layers are interrupted by trenches; gate electrodes are then arranged in such trenches.

### SUMMARY

According to the present invention, a semiconductor component and a method for producing a semiconductor component are provided. Advantageous example embodiments of the present invention are disclosed herein.

The present invention relates to semiconductor components, in particular field-effect transistors, and in particular to trenches, and their production. Different types of doping, specifically n-doping and p-doping, are used with semiconductor materials, wherein different components can be doped differently. For the sake of clarity, field-effect transistors are to be described below with a specific type of doping; n-doping is intended to be a doping of a first type, p-doping is intended to be a doping of a second type. However, it is understood that n-doping and p-doping can also be interchanged; i.e., the n-doping could be the second type of doping and the p-doping could be the first type of doping.

Such a field-effect transistor typically has a substrate layer and/or drain layer, an n-doped drift layer, a channel layer, which is usually p-doped, and an n-doped source layer. The channel layer is arranged in the vertical direction between the source layer and the drift layer. The n-doped drift layer is applied, for example, as a so-called epitaxial layer on the substrate layer and/or drain layer.

Furthermore, such a field-effect transistor has a gate trench, the so-called trench, which extends in the vertical direction from the source layer to the drift layer and is adjacent to the channel layer and at least a portion of the source layer. In addition, such a field-effect transistor may then have a gate electrode, which is introduced into the gate trench and which is insulated from the drift layer and the channel layer, e.g., by means of a so-called gate oxide.

Furthermore, such a field-effect transistor has a source contact material layer, which is adjacent to the source layer. The gate electrode, on the other hand, is insulated from the source contact material layer. Likewise, such a field-effect transistor has a drain contact material layer, which is adjacent to the substrate layer and/or drain layer. The source contact material layer is used as a source electrode or connection; accordingly, the source contact material layer is used as a source electrode or connection.

It should be mentioned that this type of field-effect transistor can have a plurality of such gate trenches and gate electrodes. In this case, so-called fins, in which the mentioned layers are formed, are formed between the gate trenches. This is a particular advantage of a trench MOSFET, since the vertical arrangement means that many gate electrodes can be arranged next to one another.

Such a field-effect transistor can be used alone or together with others, e.g., as a power switch. Preferred fields of application are, for example, in an electric drive train of a vehicle, e.g., in a current transformer (DC/DC converter, inverter) there, in charging devices for electrically powered vehicles or in solar inverters.

Semiconductor components such as field-effect transistors or transistors can generally be based on gallium nitride (GaN). This offers the possibility of producing components with lower on-resistances and simultaneously higher breakdown voltages than comparable components based on, for example, silicon (Si) or silicon carbide (SiC). GaN transistors or GaN-based transistors can be used, for example, primarily as so-called high-electron mobility transistors (HEMTs), in which the current flow takes place laterally on the top side of the substrate through a two-dimensional electron gas, which forms the transistor channel. Such lateral components can be produced by heteroepitaxy of the functional GaN layers on silicon wafers.

However, for a high breakdown voltage with a small on-resistance per unit area, vertical components, in which the current flows from the substrate front side to the substrate rear side, are more advantageous in terms of both the overall size and the electrical field distribution in the component interior. There are different concepts for the transistor channel, such as the mentioned trench-gate MOSFET (trench MOSFET or TMOS for short) and the so-called planar-gate MOSFET (also known as VDMOS).

For the manufacture of vertical components, it may be advantageous to be able to produce n-dopings and p-dopings in a spatially selective manner. In the case of silicon-based and silicon-carbide-based transistors (in particular power transistors), this can be achieved, for example, by means of ion implantation of the doping species. In the case of p-implantation, this allows, for example, the channel, as well as shielding regions, short-circuit current-limiting regions, and edge termination regions or such structures to be produced for a MOSFET. Short-circuit current-limiting structures are based on the so-called JFET effect and are therefore also referred to as JFET zones or JFET regions below.

With regard to the shielding region or shielding structures as well as the JFET regions or JFET zones, concepts of varying complexity come into consideration, which each differ in terms of the effectiveness of their shielding effect and JFET effect and vary in their space requirement.

For example, in a trench MOSFET structure, p-zones can be implanted into a gate trench next to the trench gate structures so that the lower end of the p-zone is lower than the bottom of the gate trench. This reduces the field stress on the gate dielectric in the blocking state.

In a trench-gate structure with a so-called split gate, an implanted p-zone can also be produced directly below the gate trenches (also referred to as a so-called bubble implant).

In a FinMOS structure, the so-called npn mesa zones can be reduced to narrow fins, which makes it possible to produce the channel structures and shielding structures in a particularly space-saving manner.

In the case of gallium nitride or semiconductor components based thereon, such as transistors, magnesium (Mg) is a common p-dopant. However, after the implantation of Mg atoms, they still have to be incorporated into the crystal lattice of the gallium nitride in a so-called activation step in order to be able to act as acceptors. For gallium nitride, temperatures in the range of 1300° C. and higher are necessary for this purpose.

It has been shown that gallium nitride components can be successfully activated with magnesium for gallium nitride epitaxial layers on native gallium nitride substrates but not yet for heteroepitaxially grown gallium nitride on foreign substrates.

However, the high temperatures of at least 1300° C. described above for activating implanted magnesium species as acceptors have proven to be particularly problematic when producing the shielding zones or JFET zones by means of ion implantation. From temperatures of about 800° C., the surface of gallium nitride already begins to decompose into gallium and nitrogen under normal pressure. In order to withstand the temperatures during activation without damage, complex processes in the case of overpressure (in the order of megapascals to gigapascals) would therefore have to be used or the gallium nitride would have to be protected by suitable capping materials during the process. The first approach has proven to be unusable industrially. Capping materials also cannot provide unlimited protection at temperatures of 1300° C. and higher and may even crystallize themselves at these temperatures, which makes them difficult to remove.

In addition, gallium nitride transistors that are to be produced on foreign substrates, such as silicon, sapphire, or engineered poly-AlN substrates, are limited in terms of their maximum process temperature (e.g., due to thermal stress or the melting temperature of the substrate) so that magnesium implantation and subsequent activation are not possible or at least not sensible.

According to an example embodiment of the present invention, it is now provided to diffuse one or more p-doped shielding regions, e.g., the JFET regions mentioned, into the drift layer of a gallium-nitride-based semiconductor element. These shielding regions are each located at least partially in the vertical direction below the gate trench and at least partially within the drift layer. Magnesium in particular is diffused.

This diffusion can be carried out at lower temperatures than necessary for ion implantation, namely at temperatures between 1100° C. and 1300° C. and, in particular, at a relatively constant depth profile with a dopant concentration of, for example, 2e18 cm\hat{ }-3 to 3e18 cm\hat{ }-3.

By using diffusion, GaN-based semiconductor components, such as power transistors, with p-type shielding zones or JFET zones can thus be provided without the need for an implantation process with its associated disadvantages. This can make the production process much easier.

In one example embodiment of the present invention, one or at least one of the plurality of shielding regions is a first shielding region, which is located at least substantially next to the gate trench in the horizontal direction. For example, two such first shielding regions may also be provided next to the gate trench, one to the left and one to the right thereof.

In one example embodiment of the present invention, the first shielding region is adjacent to the channel layer. It may also be provided that the first shielding region is spaced apart from the gate trench in the vertical direction.

In one example embodiment of the present invention, the source contact material layer is adjacent to the first shielding region, possibly also to the channel layer and to the source layer.

However, in one example embodiment of the present invention, it may also be provided that the first shielding region is adjacent to the gate trench.

In one example embodiment of the present invention, one or at least one of the plurality of shielding regions is a second shielding region, which is arranged vertically below the gate trench, i.e., extends in the lateral direction at least approximately the same as the gate trench. In this case, the semiconductor component may have an insulation layer, which is arranged vertically between the gate trench and the second shielding region.

In addition to the semiconductor component or transistor, the present invention also relates to a method for the production thereof. According to an example embodiment of the present invention, a substrate layer and/or drain layer is provided first, onto which an n-doped layer is applied, which comprises the n-doped drift layer. The channel layer and the n-doped source layer are then formed on the n-doped drift layer. Furthermore, the gate trench and one or at least one of the plurality of p-doped shielding regions are formed, the latter by means of diffusion of magnesium in particular. For this purpose, a shielding trench may be formed, for example.

The gate trench and shielding trench can be formed together, i.e., in a common process step, or first one and then the other. Various examples in this respect along with various advantages are explained below.

In one example embodiment of the present invention, it is also provided that a nitrogen region is formed, in particular by means of implantation, in which nitrogen region the shielding region is then formed. In this way, the thickness of the region can be controlled more precisely.

It is understood that further steps may be necessary for the final transistor chip, such as edge termination and contact path lead-throughs and the like; conventional methods can be used in this case.

Further advantages and embodiments of the present invention can be found in the description and the figures.

The present invention is shown schematically in the figures on the basis of exemplary embodiments and is described below with reference to the figures.

### BRIEF DESCRIPTION OF THE DRAWINGS

FIGS. 1 to 6 schematically show a field-effect transistor in various embodiments, according to the present invention.

FIGS. 7 to 13 schematically show sequences of methods for producing a field-effect transistor in various embodiments of the present invention.

### DETAILED DESCRIPTION OF EXAMPLE EMBODIMENTS

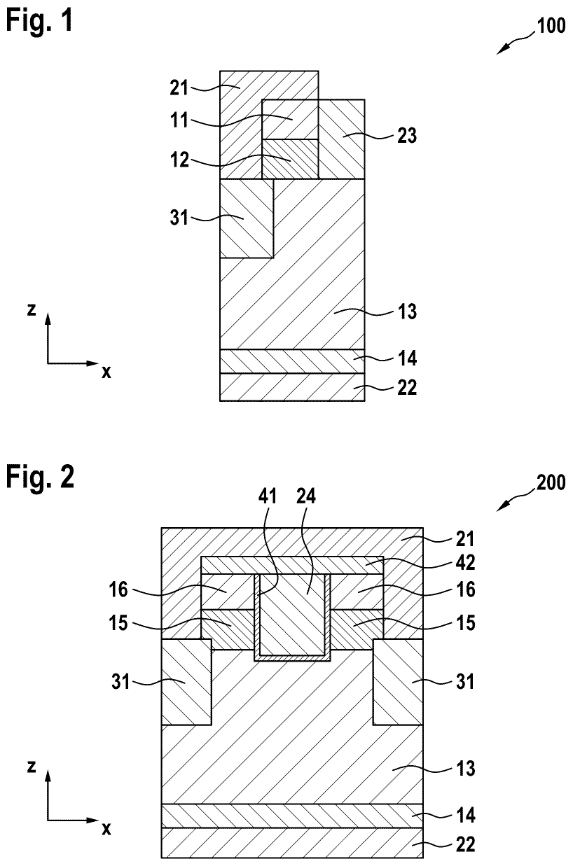

FIGS. 1 to 6 schematically show field-effect transistors in various embodiments, in particular as power transistors. Identical elements, components, or layers are denoted by the same reference signs.

The field-effect transistors are designed as so-called trench MOSFETs. Gallium nitride (GaN) is provided as the semiconductor material on which the field-effect transistors are based. The views shown are sectional views of the field-effect transistors, wherein the z-direction is a vertical direction; in each case, the field-effect transistor has a larger extent in the x-y plane (the y-direction here is into the plane of the drawing).

The field-effect transistor with an n-doping as doping of the first type and a p-doping as doping of the second type are described below. As already mentioned, the types of doping can also be reversed.

The field-effect transistor 100 according to FIG. 1 has an n-doped drift layer 13, a channel layer (electron channel-forming layer) 12, and a source layer 11. The channel layer 12 and the source layer 11 can in particular be formed on drift layer 13. The drift layer 13 is applied on a drain layer 14 of the field-effect transistor 100, wherein the latter can also comprise a substrate layer, i.e., for example, a semiconductor substrate. The field-effect transistor 100 also has a drain contact material layer 22, e.g., a drain electrode, which is adjacent to or is contacted with the drain layer 14. The field-effect transistor 100 also has a source contact material layer 21, e.g., a source electrode, which is adjacent to or is contacted with the source layer 11.

The field-effect transistor 100 also has a gate 23, which typically has a gate electrode (not shown separately here) with an insulation layer or gate oxide, by means of which the gate electrode is insulated from the drift layer 13, the channel layer 12, and the source layer 11. The gate, or the gate electrode with insulation layer, is thus placed in a gate trench.

By means of the gate 23, a conductive channel can be switched on or off at the channel layer 12, which conductive channel, in the switched-on state, makes a current flow from the source layer 11 to the drift layer 13 possible.

A first shielding region 31, e.g., a JFET region, which is produced by means of diffusion of magnesium from a magnesium source and which is, in particular, also contacted by the source electrode 21, extends into the drift layer 13. The lower edge of this first shielding region 31 extends in the vertical direction (here in the z-direction) further into the drift layer 13 than the lower edge of the gate 23 or of the corresponding gate trench.

Since the first shielding region 31 is a p-doped semiconductor zone, it offers all the advantages with regard to the electrical shielding of the gate 23 in the blocking state, the short-circuit limitation in the short-circuit case, and the reverse conductivity of the integrated body diode in reverse operation, which are conventional.

By providing shielding regions, such as the shielding structures and JFET structures 31 by means of diffusion of magnesium, these regions or zones can be produced at lower temperatures between 1100° C. and 1300° C. so that the problems described above of the activation of implanted species at temperatures of 1300° C. and higher do not occur.

Advantageously, shielding structures or JFET structures, such as the first shielding region, can thus be produced without damaging the GaN surface or entire transistor layers. In addition, it is also possible to use such shielding structures or JFET structures for GaN transistors on foreign substrates.

While the field-effect transistor 100 according to FIG. 1 shows a very general embodiment, specific embodiments are explained below.

The field-effect transistor 200 according to FIG. 2 shows an implementation in the form of a trench MOSFET with a laterally offset deep shielding layer 31. In this case, the channel layer 12 is formed as a p-doped channel layer (p-body layer) and is denoted by 15. The source layer 11 is formed as a highly doped n+GaN source layer and is denoted by 16.

A gate trench penetrates the channel layer 15 and the source layer 16 and extends into the drift layer 13. The gate 23, which is introduced into the gate trench, is formed here, by way of example, by a MOS structure comprising a gate dielectric (e.g., gate oxide) and gate electrode 24, wherein the gate electrode 24 preferably consists of polysilicon. The gate is electrically separated from the source electrode 21 by an insulation layer or an insulation dielectric 42. The source electrode 21 contacts both the source layer 16 and the channel layer 15.

The first shielding region 31 is arranged at a lateral (here in the x-direction) offset from the gate trench. It is produced by means of diffusion of magnesium from a magnesium source into the drift layer 13. The shielding region 31 is electrically connected to the source electrode 21. In other words, the shielding region 31 is at the same electrical potential as the source layer 16 and the channel layer 15.

The shielding region 31 extends substantially in the vertical direction (here in the z-direction) in the component, wherein the lower edge of the shielding region 31 extends further into the drift layer 13 than the bottom of the gate trench.

The magnesium concentration in the shielding region 31 is in particular higher than the magnesium concentration in the channel layer 15 (p-body zone) and the dopant concentration in the drift layer 13 (in the drift layer, an n-type dopant, such as silicon, can be provided as a dopant). Preferably, the magnesium concentration in the shielding region 31 is higher than 1e18 cm\hat{ }-3.

With such a structure, when the transistor is in the blocking state, a space charge zone is formed substantially in the drift layer 13, starting from the lower edge of the shielding region 31. This protects the gate dielectric 41 from high electric field stress and increases the reliability of the component.

As mentioned above, for a vertical GaN power transistor, it is advantageous to produce such a structure by means of diffusion of magnesium instead of implantation of magnesium since this avoids extremely high temperatures above 1300° C.

A further advantage of the production by means of diffusion is that the depth of the shielding region 31 can be adjusted very precisely via the temperature and duration of the diffusion. If such a zone is produced by implantation, particularly high implantation energies of 1 MeV and more are required. These process steps are particularly cost-intensive. The proposed implementation by means of diffusion circumvents this problem. Since the diffusion coefficient of magnesium in the vertical direction in the GaN crystal is higher than in the lateral direction, such a zone, which extends substantially vertically, can be produced particularly simply.

The surface of a zone or region with diffused magnesium may become rough. However, since the shielding region 31 in the proposed implementation is laterally offset from the gate, the quality of the surface in this region is not relevant for the component functionality.

Alternatively, GaN near the surface in the region of the contact can be removed, for example, by means of plasma etching, in order to optimize the surface in this way. The shielding region 31 here is thus located, in particular in the horizontal direction, at least substantially, in particular even completely, next to (but still vertically below) the gate trench.

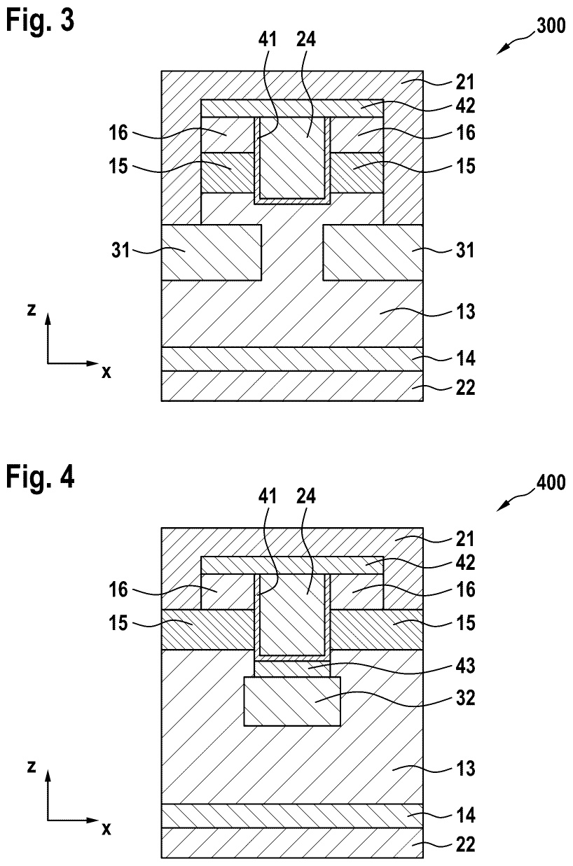

The field-effect transistor 300 according to FIG. 3 shows a variation of the trench MOSFET of FIG. 2. In this case, the shielding region 31 still extends into the drift layer 13 in such a way that its lower edge is lower than the bottom of the gate trench, but the shielding region 31 also has a significant lateral extent so that only a narrow n-conductive zone is still present in the drift layer 13 between two shielding regions 31. As a result, the shielding region 31 also acts as a JFET zone, which limits the current in the event of a short circuit by the JFET effect. However, the shielding region 31 is still located in the horizontal direction at least substantially next to the gate trench and even spaced apart therefrom in the vertical direction.

Optionally, the n-doping of the drift region between the shielding regions 31 (or JFET regions) may be increased. As a result, it is particularly advantageously possible to achieve a compromise between low on-resistance and high reliability of the component in the event of a short-circuit fault, since the short-circuit current is limited by the JFET effect, but the conductivity in the JFET zone remains high in the forward case due to the increased doping.

Preferably, the lateral distance (here in the x-direction) between the two shielding regions 31 below the gate trench is less than 800 nm. Production possibilities for such a structure using nitrogen implantation are also discussed below; nitrogen implantation can be used to provide the lateral extent of shielding regions 31 by means of diffusion, although the diffusion coefficient for magnesium is larger in the vertical direction, as described above.

The field-effect transistor 400 according to FIG. 4 shows an implementation of a vertical power transistor with a diffused bubble shielding region 32, hereinafter also referred to as the second shielding region. The second shielding region 32 lies vertically below the gate trench and is separated from the gate or gate electrode 24 and gate dielectric 41 by an additional insulation dielectric or an insulation layer 43.

With this implementation, a component with a particularly small cell size or small cell pitch and thus a particularly small specific on-resistance can be provided particularly advantageously. In addition, the gate dielectric is particularly well protected against high field stresses. Preferably, the lateral width of the second shielding region 32 is greater than the lateral width of the gate trench. In particular, the second shielding region 32 extends in the horizontal or lateral direction but at least substantially over the corresponding width of the gate trench.

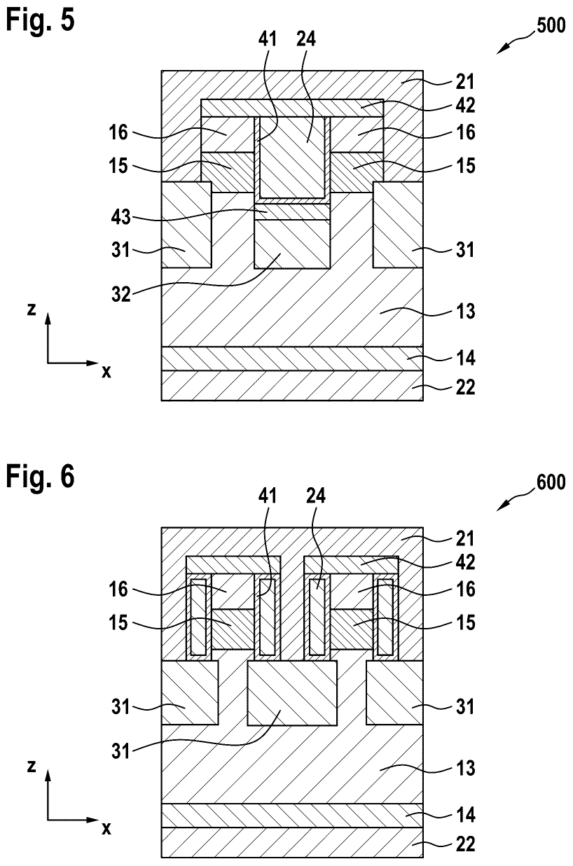

The field-effect transistor 500 according to FIG. 5 shows an implementation in which a diffused second shielding region 32 and laterally offset first shielding regions or JFET regions 31 are provided. This implementation combines the advantages of the field-effect transistors 300 and 400 according to FIGS. 3 and 4 in terms of shielding of the gate dielectric, cell pitch, and reduction of the short-circuit current.

The field-effect transistor 600 according to FIG. 6 shows an implementation in the form of a so-called FinMOS with a diffused first shielding region or JFET region 31. Here, instead of wider mesa structures made of source layer 16 and channel layer 15 (p-body zone) as in the implementations described above, narrow fins (preferably only a few 100 nanometers wide, e.g., less than 500 nm or less than 300 nm) are structured and are surrounded on both sides by a gate or a portion of a gate (each with gate electrode 24 and gate dielectric 41).

This makes it possible to achieve a particularly high channel density, whereby the specific on resistance can be reduced, and to reduce the short-circuit current particularly efficiently. Since the fins at a few 100 nanometers are particularly narrow, a low doping of the channel layer 15 can be selected since the fin effect with a gate electrode on both sides can deplete the channel layer 15 or p-body zone despite low doping.

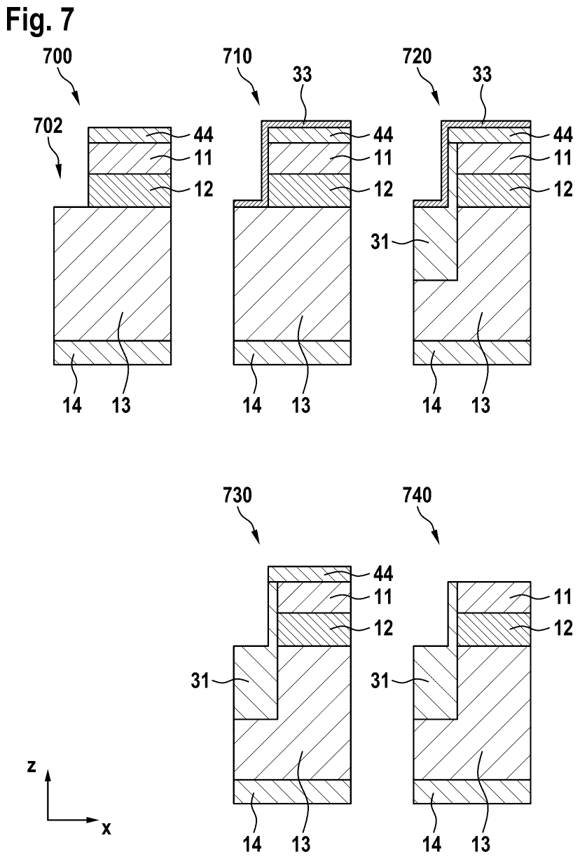

FIGS. 7 to 13 show schematic sequences of methods for producing a field-effect transistor in various embodiments. Identical elements, components, or layers are denoted by the same reference signs as in FIGS. 1 to 6.

FIG. 7 shows an embodiment of a production method for producing a diffused shielding region, in particular a first shielding region 31. In a step 700, a trench 702 is produced at the location where the diffused shielding region will be produced later. This can be carried out, for example, by dry chemical plasma etching with a masking layer 44. For example, the masking layer 44 may comprise or be SiO2 or SiN or a SiON. The trench may, for example, be produced very shallowly, in the limiting case not produced at all (i.e., only the masking layer is removed locally), or the trench may extend into the drift layer 13.

In step 710, a magnesium source layer 33 is applied, which has the property of providing magnesium. The magnesium source layer 33 may, for example, be pure magnesium, magnesium oxide, magnesium fluoride, or a magnesium gallium nitride mixture. However, a silicon-free and oxygen-free magnesium compound is preferred. It can be produced, for example, by means of methods such as sputtering or evaporation.

In step 720, magnesium is diffused from the magnesium source layer 33 into the gallium nitride layers. The diffusion can be carried out at temperatures between 1100° C. and 1300° C. For example, a plurality of temperature steps at different temperatures may also be used. During diffusion, the magnesium diffuses preferably in the vertical direction (here in the z-direction) and only to a lesser extent in the lateral direction. This property is due to a higher diffusion coefficient for magnesium in the vertical direction of the material.

The masking layer 44 is used to prevent the diffusion of magnesium so that no magnesium diffuses through the surface of the source layer 11. Advantageously, magnesium thus diffuses laterally from the trench sidewall into the source layer 11 and the channel layer 12 and thereby automatically results in the same potential in the shielding region 31 and the channel layer 12.

In step 730, the magnesium source layer 33 is removed. In step 740, the masking layer 44 is removed. Both steps can be carried out by wet chemical etching.

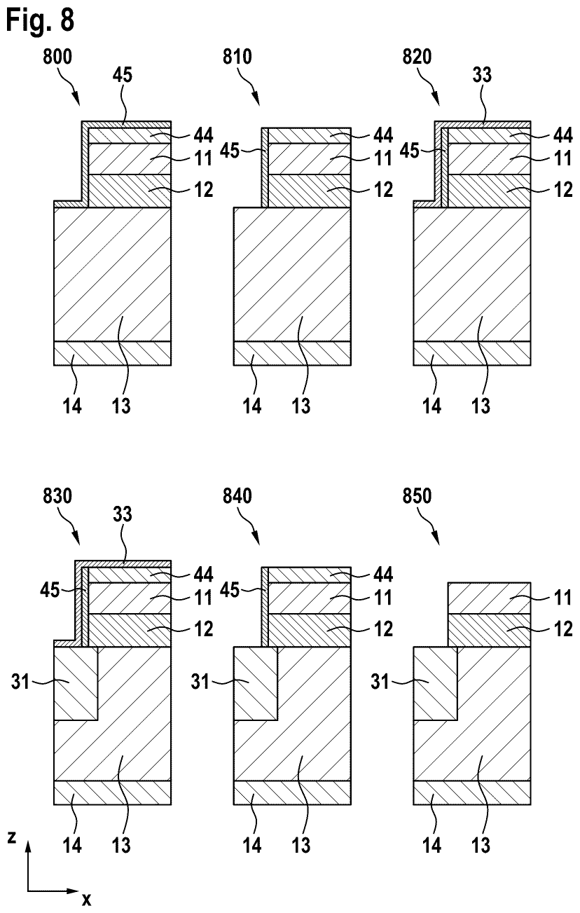

FIG. 8 shows another embodiment of a production method. Here, in addition to the masking layer 44 according to FIG. 7, a spacer layer 45 is produced on the sidewall of the trench, step 800. This spacer layer may also be a dielectric such as SiO2 or SiN.

Such a spacer layer 45 may be produced, for example, by first depositing it conformally over the entire structure and subsequently removing it with a directed dry chemical etching process that etches predominantly on the horizontal faces. As a result, the spacer layer 45 on the sidewall of the trench is retained.

The further steps 810 to 850 then correspond to steps 700 to 740 according to FIG. 7, wherein, in step 850, the spacer layer 45 can also be removed.

The advantage of this production variant is that the lateral diffusion can be controlled very precisely via the very well controllable thickness of the spacer layer 45. This may be advantageous since the JFET effect in a shielding region or JFET region 31 is determined via the lateral diffusion. Furthermore, such a production method is advantageous for components as shown in FIG. 4, namely, for example, a field-effect transistor with a bubble diffusion, since no diffusion takes place on the sidewall in this case. This is obviously required for a bubble diffusion so that the bubble diffusion does not change the channel properties.

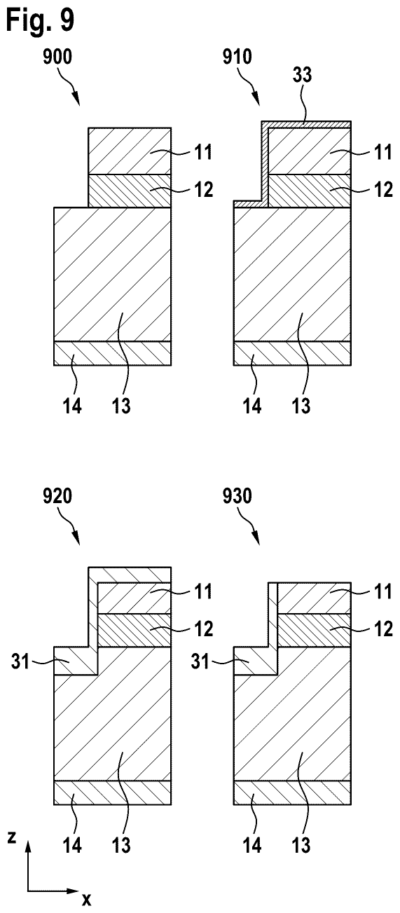

FIG. 9 shows a further embodiment of a production method. Here, a masking layer is completely dispensed with, i.e., after step 900 with the provision of the layers, the magnesium source layer 33 is applied directly onto the surface structured with the trench, step 910, and diffused, step 920.

In step 930, the magnesium source layer 33 is removed and the diffused magnesium on the surface of the source layer 11 is removed. This may be carried out, for example, by chemical mechanical polishing (CMP). The shielding region 31 is thus obtained, step 930.

The advantage of this production method is that a masking layer can be dispensed with. However, the production method is limited to shallow diffusion since the diffusion depth must be provided as thickness in the source layer 11. The production method is in particular advantageous if the deposition of the masking layer 44 requires a technically difficult-to-implement alignment tolerance to an already existing trench.

The production variants in FIGS. 7 to 9 show different possibilities to provide the masking.

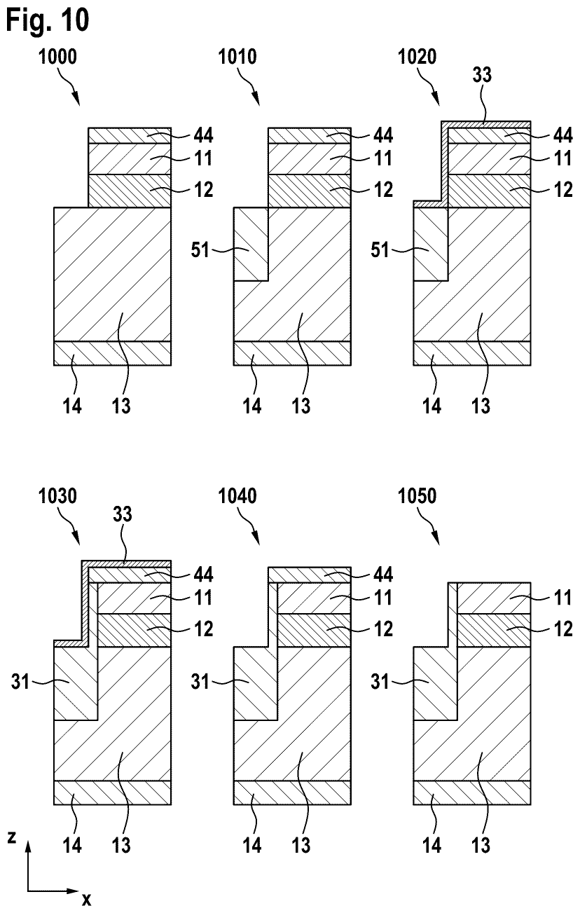

FIG. 10 shows a further embodiment of a production method for a possibility of controlling the diffusion profile. The diffusion of magnesium, which has been implanted in high concentration but shallowly into a GaN layer, can be controlled by the implantation of a deeper nitrogen profile. Without nitrogen implantation, the magnesium diffuses deeper into the GaN crystal than with nitrogen implantation. A very deep and in particular uncontrolled diffusion of magnesium can have a negative impact on the component design.

In FIG. 10, the masking layer 44, which is applied in step 1000, is additionally used to produce a nitrogen zone 51 in a self-aligned manner by means of nitrogen ion implantation, step 1010. Preferably, nitrogen concentrations in the range of 3e18 cm\hat{ }-3 to 3e19 cm\hat{ }-3 are implanted here.

The following steps 1020 to 150 correspond to steps 710 to 740 according to FIG. 7. The profile of the diffused shielding region 31 is substantially determined by the profile of the nitrogen zone 51.

In the above-described variants, the ratio of vertical and lateral diffusion of magnesium is determined by the diffusion coefficients. However, by means of the implantation of the nitrogen zone 51, diffusion can be better controlled. In particular in combination with the spacer layer 45 according to FIG. 8, the magnesium profile can thus be adjusted very flexibly.

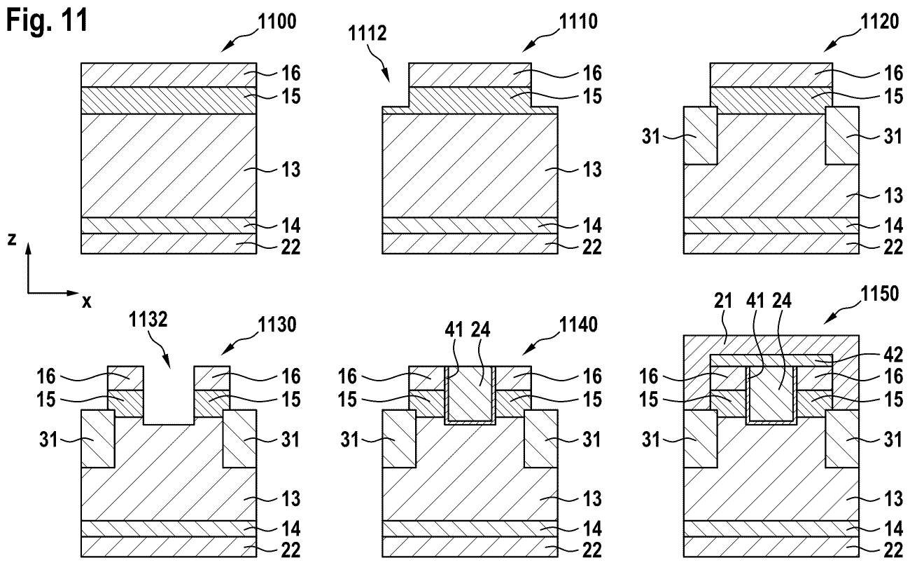

FIGS. 11 to 13 show embodiments of a production method for different implementations within a semiconductor process, each using the example of a trench MOSFET.

According to FIG. 11, after providing the layers, step 1100, the trench 1112 for the shielding region or JFET region 31 is created, step 1110. The shielding region or JFET region 31 can then be produced according to one of the embodiments of a production method described above, indicated here with step 1120. The gate trench 1132 is created in step 1130, the gate is formed in step 1140, and the transistor cell is completed in step 1150.

The advantage of this production method is that the high-temperature diffusion processes are completed before the gate is formed and that there are thus no restrictions on the gate in terms of its maximum temperature budget. Furthermore, the later inversion channel on the sidewall of the gate trench is not yet accessible during diffusion, so that there is a low risk of contamination of the channel zone (on the sidewall of the gate trench) with magnesium.

A further advantage is that, as illustrated in FIG. 11, different depths can be used for the shielding trench 1112 and the gate trench 1132. This allows the depth of the shielding region 31 to be adjusted very flexibly. This variant can be combined particularly elegantly with the nitrogen implantation according to FIG. 10, wherein the masking layer for producing the shielding trench acts as an implantation mask for the nitrogen zone 51.

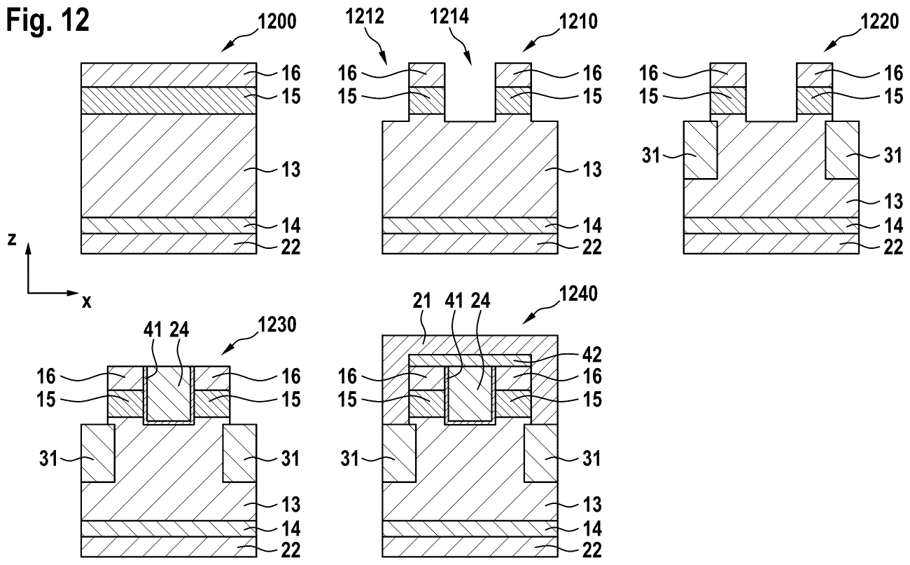

In the method in FIG. 12, after providing the layers in step 1200, the gate trench 1214 and shielding trench 1212 are formed simultaneously, step 1210. In step 11220, the magnesium is diffused only in the region of the shielding trench with the aid of a masking layer 44 (not shown here). Steps 1230 and 1240 then correspond to steps 1140 and 1150.

This variant has the advantage that there is no alignment tolerance between the gate trench and the shielding trench and that the shielding regions or JFET regions are thus exactly symmetrical with respect to the gate trench. This is advantageous for the JFET short-circuit limitation property. The disadvantage is that a suitable masking layer must be used in this case to ensure that the channel zone in the gate trench is not contaminated by magnesium.

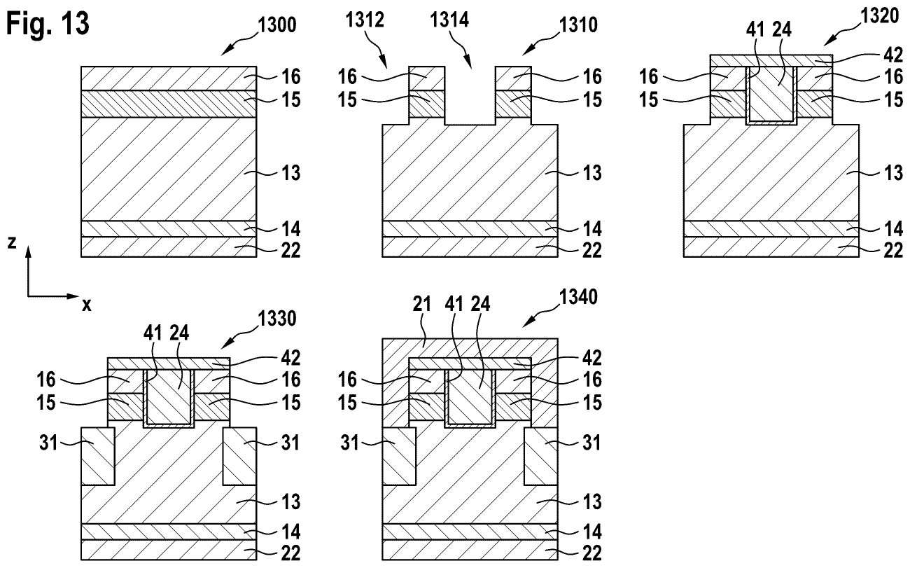

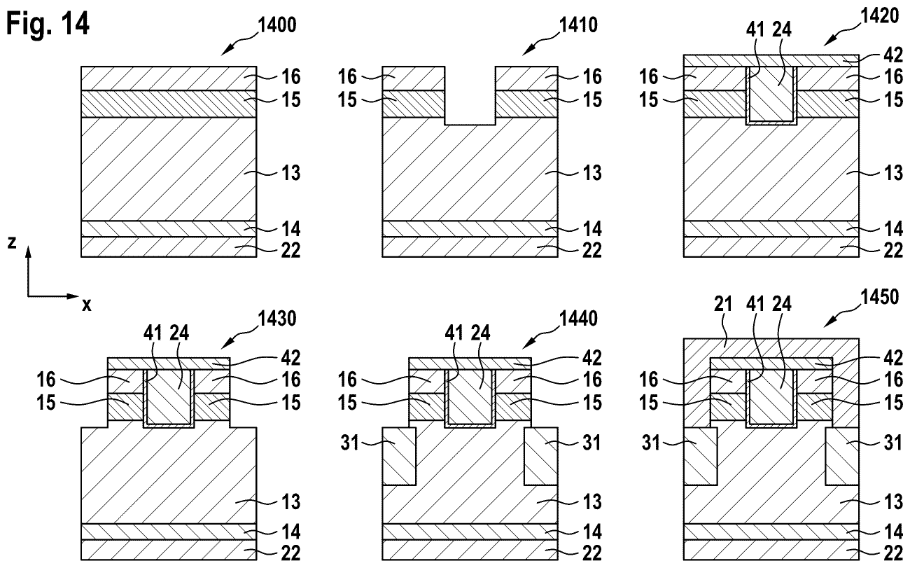

In the method in FIG. 13, after providing the layers in step 1300, the gate trench 1314 and shielding trench 1312 are formed simultaneously, step 1310. However, the gate or gate complex is then produced first, step 1320, before the shielding region 31 is diffused, step 1330. This is advantageous since the gate can be completed entirely without metal before magnesium contamination can occur. The disadvantage is that, in this case, the gate complex has to withstand the high temperatures during magnesium diffusion. This variant can be combined particularly elegantly with the nitrogen implantation of FIG. 10, wherein the insulation layer 42 acts as an implantation mask for the nitrogen zone 51. Step 1340 corresponds to step 1150 or 1240.

In the method in FIG. 14, after providing the layers in step 1400, the gate trench and the gate complex are formed first, step 1410 or 1420. Only thereafter, the shielding trench is formed, step 1430, and the magnesium is diffused, step 1440. This method may be advantageous if the gate formation involves processes that rely on the absence of any topography on the wafer surface other than the gate trench. This is the case, for example, for a mask-free recess process for a gate trench filled with poly-silicon. Furthermore, the entire process during the front end can be kept metal-free in this variant as well. Step 1440 corresponds to step 1150 or 1240.

The proposed diffusion of magnesium can be particularly well recognized in a product since the diffusion results in a constant magnesium concentration profile up to a certain depth, whereas, in the case of implantation, the magnesium is implanted in a plurality of so-called injections, with each injection leaving behind an approximately Gaussian profile, which thus differs from the constant profile after diffusion.

1-15. (canceled).

16. A semiconductor component, which is based on gallium nitride, wherein the semiconductor component comprises:
a substrate layer and/or drain layer;
a first-type-doped drift layer;
a channel layer, which is second-type-doped;
a first-type-doped source layer, wherein the channel layer is arranged in a vertical direction between the source layer and the drift layer;
a gate trench, which extends in the vertical direction from the source layer to the drift layer and is adjacent to the channel layer and at least a portion of the source layer;
at least one second-type-doped shielding region, each of which is located at least partially in the vertical direction below the gate trench and at least partially within the drift layer;
wherein at least one of the at least one shielding region is diffused.

17. The semiconductor component according to claim 16, wherein the semiconductor component is a transistor.

18. The semiconductor component according to claim 16, wherein each of the at least one shielding region is at least partially formed by diffused magnesium.

19. The semiconductor component according to claim 16, wherein at least one of the at least one shielding region is a first shielding region, which is located at least substantially next to the gate trench in a horizontal direction.

20. The semiconductor component according to claim 19, wherein the first shielding region is adjacent to the channel layer.

21. The semiconductor component according to claim 19, wherein the first shielding region is spaced apart from the gate trench in the vertical direction.

22. The semiconductor component according to claim 19, further comprising a source contact material layer, which is adjacent to the first shielding region.

23. The semiconductor component according to claim 22, wherein the source contact material layer is adjacent to the channel layer and the source layer.

24. The semiconductor component according to claim 19, wherein the first shielding region is adjacent to the gate trench.

25. The semiconductor component according to claim 19, wherein at least one of the at lest one shielding regions is a second shielding region, which is arranged vertically below the gate trench, and wherein the semiconductor component has an insulation layer, which is arranged vertically between the gate trench and the second shielding region.

26. The semiconductor component according to claim 16, further comprising a gate electrode, which is introduced into the gate trench and which is insulated from the drift layer and the channel layer and the source layer.

27. The semiconductor component according to claim 16, further comprising a drain contact material layer, which is adjacent to the substrate layer and/or drain layer.

28. A method for producing a semiconductor component, the semiconductor component being based on gallium nitride and including:
a substrate layer and/or drain layer,
a first-type-doped drift layer,
a channel layer, which is second-type-doped,
a first-type-doped source layer, wherein the channel layer is arranged in a vertical direction between the source layer and the drift layer,
a gate trench, which extends in the vertical direction from the source layer to the drift layer and is adjacent to the channel layer and at least a portion of the source layer,
at least one second-type-doped shielding region, each of which is located at least partially in the vertical direction below the gate trench and at least partially within the drift layer,
wherein at least one of the at least one shielding region is diffused,
wherein the method comprises the following steps:
providing the substrate layer and/or drain layer;
applying a layer including the first-type-doped drift layer;
forming the channel layer and the first-type-doped source layer,
forming the gate trench; and
forming at least one of the at least one second-type-doped shielding region by diffusion.

29. The method according to claim 28, furthermore comprising:
forming a shielding trench before forming the at least one of the second-type-doped shielding region.

30. The method according to claim 29, wherein:
the gate trench and the shielding trench are formed together, or
the gate trench is formed first and then the shielding trench, or
the shielding trench is formed first and then the gate trench.

31. The method according to claim 28, furthermore comprising:
forming a nitrogen region by implantation;
wherein the at least one second-type-doped shielding region is formed in the nitrogen region by diffusion.
